(19) United States
(12) Patent Application Publication
(10) Pub. No.: US 2010/0119733 A1
(43) Pub. Date: May 13, 2010

(54) METHOD OF IMMOBILIZING ACTIVE MATERIAL ON SURFACE OF SUBSTRATE

(75) Inventors: An-Soon KIM, Daejon (KR); Chil-Seong AH, Daejon (KR); Hye-Kyoung YANG, Daejeon (KR); Chan-Woo PARK, Daejeon (KR); Jong-Heon YANG, Daejon (KR); Chang-Geun AHN, Daejeon (KR); In-Bok BAEK, Cheongju-si (KR); Tae-Youb KIM, Seoul (KR); Gun-Yong SUNG, Daejeon (KR); Seon-Hee PARK, Daejeon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics and Telecommunications Research Institute, Daejeon (KR)

(21) Appl. No.: 12/419,527

(22) Filed: Apr. 7, 2009

(30) Foreign Application Priority Data
Nov. 11, 2008 (KR) 10-2008-0111433

(51) Int. Cl. C23C 16/513; B05D 3/06

(52) U.S. Cl. 427/578; 427/248.1; 427/255.27

(57) ABSTRACT

Provided is a method of immobilizing an active material on a surface of a substrate. The method including cleaning a substrate, functionalizing a surface of the substrate using a hydroxyl group, functionalizing the surface of the substrate at atmospheric pressure using a vaporized organic silane compound, and immobilizing an active material to an end of the surface of the substrate. Therefore, since evacuation or the use of carrier gas is not necessary, a uniform, high-density, single-molecular, silane compound film can be formed inexpensively, simply, and reproducibly, and an active material can be immobilized to the single-molecular silane compound film.

### CROSS-REFERENCE TO RELATED APPLICATIONS

This U.S. non-provisional patent application claims priority under 35 U.S.C. §119 of Korean Patent Application No. 10-2008-0111433, filed on Nov. 11, 2008, the entire contents of which are hereby incorporated by reference.

### BACKGROUND OF THE INVENTION

The present invention disclosed herein relates to a method of immobilizing an active material on a surface of a substrate.

Recently, there has been social and international attention on the convergence among information-technology (IT), bio-technology (BT), and nano-technology (NT). Together with IT, BT and NT draw attention as key technology for the 21st century. Such technologies are considered to be developed through inter-technological and inter-industrial union and convergence rather than they are individually developed. For this, it is necessary to immobilize bio-materials and functional materials on existing electronic, magnetic, and optical devices, and thus what is considered to be important is a method of chemically functionalizing the surface of a device and immobilizing a bio-material and a functional material to the surface of the device in a manner such that high reproducibility, mass productivity, and process yield can be guaranteed. For reproducible chemical activation, it is required to coat a surface with a thin film having a uniform thickness. Particularly, in the case of a target material detection sensor such as a bio sensor and an environmental material sensor, a receptor of a target material should be densely immobilized to the surface of the sensor so as to increase the sensitivity of the sensor to the target material.

In a representative method for immobilizing a bio or functional material to a silicon based device or a device having an oxidized surface, a substrate is modified by reacting the substrate with a solution prepared by dissolving silane in a solvent such as ethanol or toluene. However, in the reaction using the silane-containing solution, a multi-layer film can be formed due to a polymer reaction, or an uneven film such as a film having islands can be formed according to the amount of water contained in the solution. Moreover, due to high sensitivity to surrounding environments, reproducible surface functionalization is not ensured. To address these limitations, a method of functionalizing an oxidized surface using vaporized silane has been proposed. In detail, the proposed method is a chemical vapor deposition (CVD) method, in which an oxidized surface substrate is loaded in a vacuum chamber, and silane is carried and deposited onto the oxidized surface of the substrate generally by using nitrogen gas as carrier gas. In the silane depositing CVD method, since a solution reaction is not necessary, a more uniform silane molecule film can be reproducibly formed. However, the CVD method requires expensive and complicated equipment due to the use of the vacuum chamber and carrier gas.

### SUMMARY OF THE INVENTION

The present invention provides an inexpensive and simple method of reproducibly forming a uniform, high-density, single-molecular film using a silane compound.

The present invention also provides a method of immobilizing an active material on a surface of a substrate where a single molecular film is formed using a silane compound for allowing immobilization of another active material to the surface of the substrate.

Embodiments of the present invention provide a method of immobilizing an active material on a surface of a substrate, the methods including: cleaning a substrate; functionalizing a surface of the substrate using a hydroxyl group; functionalizing the surface of the substrate at atmospheric pressure using a vaporized organic silane compound; and immobilizing an active material to an end of the surface of the substrate.

In some embodiments, the cleaning of the substrate may include: placing the substrate in boiling acetone; placing the substrate in boiling methanol; placing the substrate in a mixture solution of a sulfuric acid and a hydrogen peroxide; and placing the substrate in a mixture of an ammonium fluoride and a hydrofluoric acid.

In some embodiments, the functionalizing of the surface of the substrate at atmospheric pressure using the vaporized organic silane compound may include: placing the substrate in a reaction vessel; filling a solution vessel with an organic silane compound in an inert gas atmosphere, the solution vessel being disposed inside the reaction vessel at a position spaced apart from the substrate; and vaporizing the organic silane compound filled in the solution vessel. In some embodiments, the organic silane compound may have the chemical formula: R₁—(CH₂)ₙ—Si(R₂R₃R₄) where R₁ is at least one selected from the group consisting of ended or branched, acyclic or cyclic unsaturated hydrocarbon, thiol, carbonyl, carboxyl, amine, imine, nitro, hydroxyl, phenyl, nitrile, aldehyde, isocyano, and isothiocyano groups, n is a natural number ranging from 1 to 8, and each of R₂, R₃, and R₄ is at least one selected from the group consisting of an alkyl group, an alkoxy group, and chlorine.

In other embodiments, the active material may be a bio material, and the R₁ is at least one selected from the group consisting of aldehyde, isocyano, and isothiocyano groups.

In still other embodiments, prior to the immobilizing of the active material, the method may further include functionalizing the surface of the substrate using a functional group capable of reacting with the active material.

In even other embodiments, the functional group may be at least one selected from the group consisting of an amine group, a hydrazine group, a hydrazone group, a cyano group, an aldehyde group, an isocyano group, an isothiocyano group, a halogen group, a nitro group, a thiol group, and a Grignard compound.

In yet other embodiments, the active material may be a bio material, and the functional group may be at least one selected from the group consisting of an aldehyde group, an isocyano group, and an isothiocyano group.

In further embodiments, the active material may be a functional material, and the functional group may be at least one selected from the group consisting of acyclic or cyclic unsaturated hydrocarbon, thiol, carbonyl, carboxyl, amine, imine, nitro, hydroxyl, phenyl, nitrile, isocyano, and isothiocyano groups.

In still further embodiments, the active material may be at least one selected from the group consisting of a bio material, a functional material, a nano material, and a polymer.

In even further embodiments, the functionalizing of the surface of the substrate using the hydroxyl group may include treating the surface of the substrate using oxygen plasma.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a flowchart for explaining a method of immobilizing an active material on a surface of a substrate according to an embodiment of the present invention;

FIG. 2 is a schematic view illustrating a reaction vessel according to an embodiment of the present invention;

FIG. 3 is a schematic view for explaining a method of immobilizing gold (Au) nanoparticles conjugated with DNAs (Au-DNA conjugates) to a surface of a substrate in an experimental example carried out according to an embodiment of the present invention;

FIG. 4 is a scanning electron microscope (SEM) image illustrating a substrate surface to which Au-DNA conjugates are immobilized in an experimental example carried out according to an embodiment of the present invention; and

FIG. 5 is a SEM image illustrating a substrate surface to which Au-DNA conjugates are immobilized according to typical technology.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

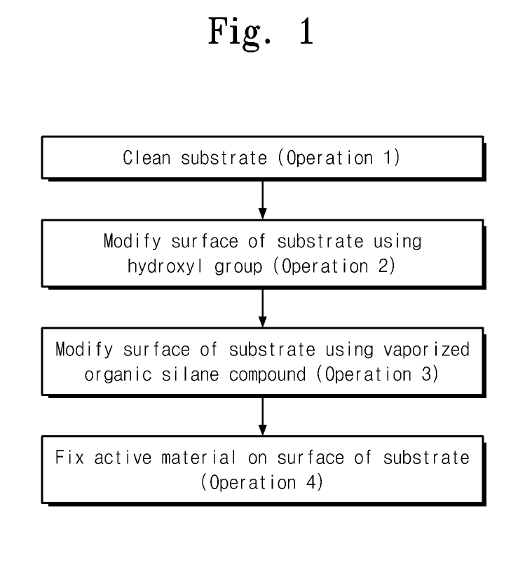

FIG. 1 is a flowchart for explaining a method of immobilizing an active material on a surface of a substrate according to an embodiment of the present invention.

Referring to FIG. 1, the method of the current embodiment may include cleaning a substrate (operation 1), functionalizing a surface of the substrate using a hydroxyl group (operation 2), functionalizing the surface of the substrate at atmospheric pressure using a vaporized organic silane compound (operation 3), and immobilizing an active material to an end of the surface of the substrate (operation 4). The method will now be explained in more detail.

(Operation 1: Cleaning of Substrate)

The substrate may include at least one selected from the group consisting of crystalline silicon, crystalline germanium, amorphous silicon, amorphous germanium, SiₓN_{y}, SiO₂, Al₂O₃, TiO₂, Fe₂O₃, SnO, SnO₂, Ag₂O, CuO, Ce₂O₃, CeO₂, CoO, CO₃O₄, glass, compound semiconductor, and oxidized plastic. In operation 1, the substrate is placed in boiling acetone for about 10 seconds to about 1 hour (for example, for 1 minute to 5 minutes). Next, the substrate is placed in boiling methanol for about 10 seconds to about 1 hour (for example, for 1 minute to 5 minutes). Then, the substrate is rinsed using deionized water for about 10 seconds to about 1 hour (for example, for 1 minute to 5 minutes).

If the substrate includes at least one selected from the group consisting of crystalline silicon, crystalline germanium, amorphous silicon, amorphous germanium, SiₓN_{y}, SiO₂, glass, compound semiconductor, and oxidized plastic, the substrate is placed in an SPM solution (having a sulfuric acid: hydrogen peroxide ratio=1:1) for about 10 seconds to about 5 hour (for example, for 1 minute to 1 hour) and is rinsed using deionized water for about 1 minute to 10 minutes. Thereafter, to remove an oxidized surface from the substrate, the substrate is placed in a buffered oxide etchant (BOE) solution (having an ammonium fluoride: hydrofluoric acid ratio=30:1) for about 1 second to about 1 hour (for example, for 3 seconds to 1 minute) and is then rinsed using deionized water.

If the substrate includes at least one selected from the group consisting of Al₂O₃, TiO₂, Fe₂O₃, SnO, SnO₂, Ag₂O, CuO, Ce₂O₃, CeO₂, CoO, and CO₃O₄, such SPM-solution and BOE-solution treatments may not be performed on the surface of the substrate.

(Operation 2: Functionalization of Surface of Substrate using Hydroxyl Group)

In operation 2, to make the surface of the substrate hydrophilic and activate the surface of the substrate chemically, hydroxyl groups are formed on the surface of the substrate by treating the surface of the substrate using, for example, oxygen plasma. The oxygen plasma treatment may be performed with plasma power of about 25 W to about 500 W for about 1 minute to about 30 minutes.

(Operation 3: Functionalization of Surface of Substrate at Atmospheric Pressure using Vaporized Organic Silane Compound)

In operation 3, an organic silane compound may be vaporized at atmospheric pressure as follows. First, after operation 2, the substrate is placed in a reaction vessel. In the reaction vessel, inert gas is filled at atmospheric pressure, and a solution vessel is placed at a predetermined distance from the substrate. An organic silane compound is put into the reaction vessel. Then, after closing the top side of the reaction vessel air-tightly, the reaction vessel is carried into a heater to vaporize the organic silane compound.

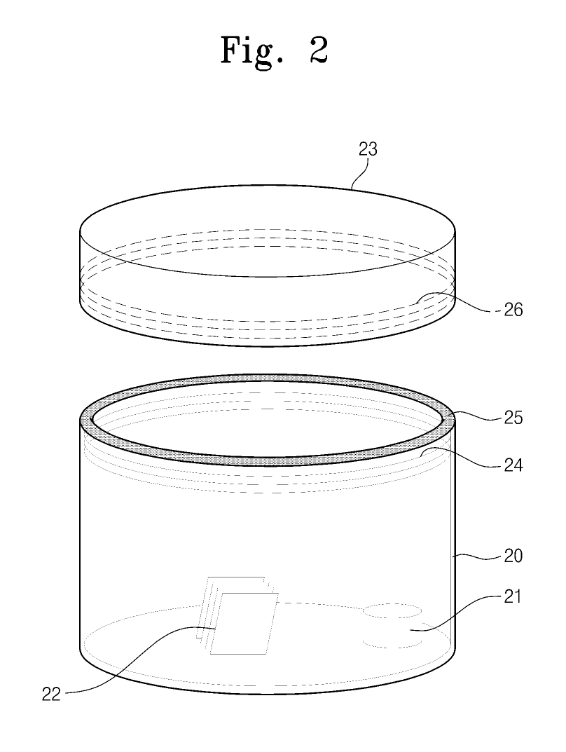

An example of the reaction vessel is illustrated in FIG. 2. Referring to FIG. 2, a reaction vessel 20 is configured to be coupled with a cap 23 using threads 24 and 26. The reaction vessel 20 may be formed of at least one material selected from the group consisting of Teflon, aluminum, stainless steel, and glass. A rubber o-ring 25 may be disposed on an upper edge portion of the reaction vessel 20 for providing more securable sealing. Substrates 22 are placed on the inner bottom side of the reaction vessel 20. A plurality of grooves (not shown) may be formed in the inner bottom side of the reaction vessel 20 for immobilizing the substrates 22. A solution vessel 21 is placed on the inner bottom side of the reaction vessel 20 at a position spaced a predetermined distance from the substrates 22, and an organic silane compound solution is filled in the solution vessel 21.

Substrates 22 processed in operation 2 and a solution containing an organic silane compound are placed in the reaction vessel 20. The organic silane compound may have the chemical formula: R₁—(CH₂)ₙ—Si(R₂R₃R₄) where R₁ is at least one selected from the group consisting of ended or branched, acyclic or cyclic unsaturated hydrocarbon, thiol, carbonyl, carboxyl, amine, imine, nitro, hydroxyl, phenyl, nitrile, aldehyde, isocyano, and isothiocyano groups, and n denotes an integer ranging from 1 to 8. Each of R₂, R₃, and R₄ is at least one selected from the group consisting of an alkyl group, an alkoxy group, and chlorine. About 2 μL to about 1000 μL of organic silane compound solution (for example, 10 μL to 300 μL of organic silane compound solution) may be filled in the solution vessel 21. After closing the reaction vessel 20 with the cap 23, the reaction vessel 20 is placed in a heater such as an oven. The oven is kept at a temperature of about 50° C. to about 300° C. (for example, 100° C. to 200° C.) for 1 minute to 1 hour (for example, 5 minutes to 10 minutes) for allowing reaction in the reaction vessel 20. In this way, the surfaces of the substrates 22 are silanized.

(Operation 4: Immobilization of Active Material to End of Surface of substrate)

The active material may be at least one selected from the group consisting of a bio material, a functional material, a nano material, and a polymer. The bio material may be at least one selected from the group consisting of DNA, RNA, antibody, antigen, oligopeptide, polypeptide, protein, enzyme, glucose, carbohydrate, anti-cancer material, amino acid, cell, bacterium, and virus. The functional material may be at least one selected from the group consisting of a sterilizing active material, a gas adsorbing material, a chemical, molecules or a polymer having memory characteristics, molecules or a polymer having switching characteristics, a magnetic material, and a photonics material. The nano material may have a size in the range from about 0.1 nm to about 999 nm and may be at least one selected from the group consisting of quantum dots, nano dots, nano wires, nano tubes, nano porous materials, nano plates, nano rods, nano needles, nano powders, and nano cubes. The polymer may have a molecular weight of 10,000 or higher and may be a carbon compound including nitrogen, oxygen, or sulfur.

Depending on the kind of the active material, the kind of the R₁ of the organic silane compound used in operation 3 may be determined. For example, if the active material is a bio material, the R₁ may be at least one selected from the group consisting of aldehyde, isocyano, and isothiocyano groups. If the R₁ of the organic silane compound is not sufficiently reactive for chemically coupling with the active material, the substrate silanized in operation 3 may be modified prior to operation 4 by using a functional group that can react with the active material. In this case, the functional group may be at least one selected from the group consisting of an amine group, a hydrazine group, a hydrazone group, a cyano group, an aldehyde group, an isocyano group, an isothiocyano group, a halogen group, a nitro group, a thiol group, and a Grignard compound. In detail, if the active material is a bio material, the functional group may be at least one selected from the group consisting of an aldehyde group, an isocyano group, and an isothiocyano group. If the active material is a functional material, the functional group may be at least one selected from the group consisting of acyclic or cyclic unsaturated hydrocarbon, thiol, carbonyl, carboxyl, amine, imine, nitro, hydroxyl, phenyl, nitrile, isocyano, and isothiocyano groups.

### Experimental Example

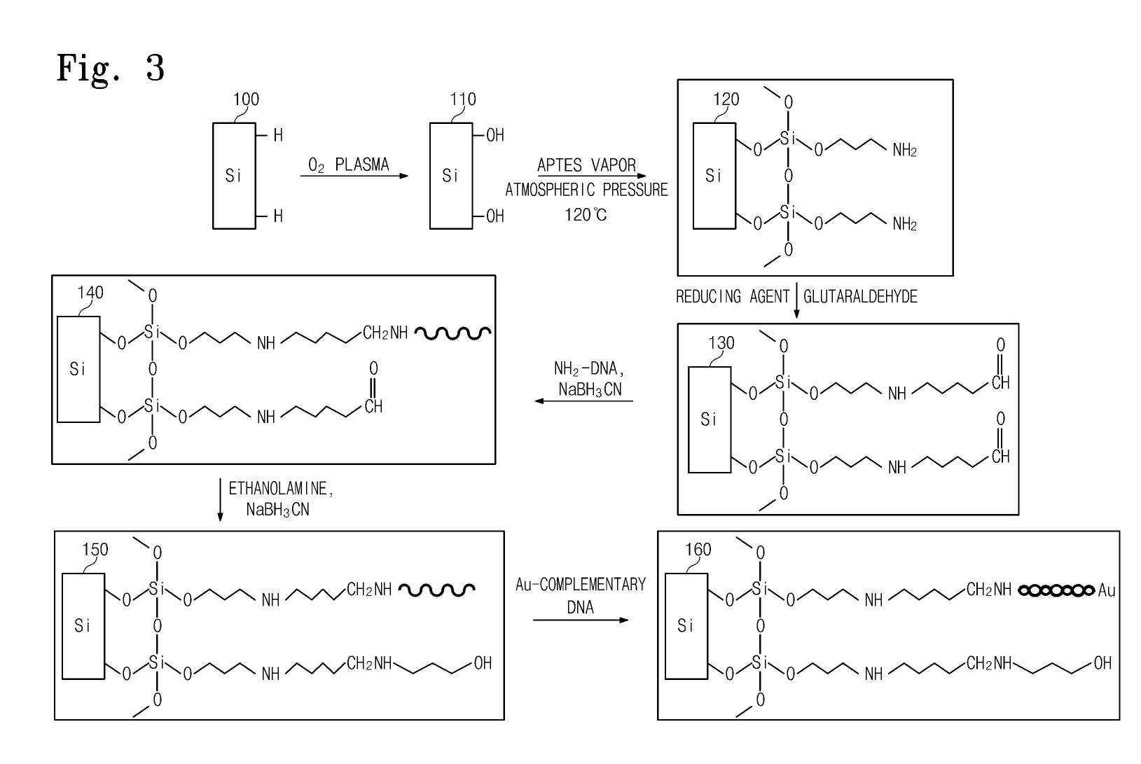

An experimental example will now be explained with reference to FIG. 3.

(Operation 1: Cleaning of Substrate)

A silicon substrate was prepared. The silicon substrate was placed in boiling acetone for about 5 minutes and in boiling methanol about 5 minutes. Next, the substrate was rinsed using deionized water to remove dust, particles, and an organic material from the surface of the silicon substrate. Thereafter, the silicon substrate was placed in an SPM solution for about 10 minutes to remove a remaining material such as an organic material and a metal from the surface of the silicon substrate, and the silicon substrate was rinsed using deionized water for about 3 minutes. Then, the silicon substrate was placed in a BOE solution (having an ammonium fluoride: hydrofluoric acid ratio=30:1) for about 10 seconds to remove an oxidized surface from the silicon substrate and obtain a clean silicon surface (refer to reference numeral 100 of FIG. 3).

(Operation 2: Functionalization of Surface of Substrate using Hydroxyl Group)

An oxygen plasma treatment was performed on the silicon substrate at about 40 Pa with about 50-W power for about 5 minutes so as to form hydroxyl groups on the surface of the silicon substrate (refer to reference numeral 110 of FIG. 3).

(Operation 3: Functionalization of Surface of Substrate at Atmospheric Pressure using Vaporized Organic Silane Compound)

The silicon substrate 110 having hydroxyl groups was placed in the reaction vessel 20 illustrated in FIG. 2, and 100 μL of 3-aminopropyltriethoxysilane (APTES) solution was filled in the solution vessel 21 illustrated in FIG. 2. After closing the cap 23 of the reaction vessel 20 at atmospheric pressure, the reaction vessel 20 was placed in an about 120-° C. oven for about 10 minutes to allow reaction in the reaction vessel 20, thereby forming amine groups on the surface of the silicon substrate (refer to reference numeral 120 of FIG. 3).

In addition, the silicon substrate 120 modified with amine groups was placed in a solution (prepared by dissolving glutaraldehyde in deionized water to obtain a glutaraldehyde solution including 25% by weight of glutaraldehyde and adding a NaBH₃CN to the glutaraldehyde solution at a concentration of 10 mg/mL) for about 4 hours at room temperature so as to functionalize the surface of the silicon substrate with aldehyde groups (refer to reference numeral 130 of FIG. 3).

(Operation 4: Immobilization of Active Material to End of Surface of Substrate)

The aldehyde-modified surface of the silicon substrate 130 was reacted with DNAs (composed of 12 base sequences having end amine groups) and 4 mM of NaBH₃CN (a reducing agent) so as to immobilize the DNAs through strong and stable chemical carbon-nitrogen bonding (refer to reference numeral 140 of FIG. 3). Remaining aldehyde groups not participated in the reaction were reacted with ethanolamine and NaBH₃CN to replace the aldehyde groups with less reactive hydroxyl groups (refer to reference numeral 150 of FIG. 3).

The immobilized DNAs of the silicon substrate were reacted with complementary DNAs conjugated with 13-nm gold (Au) particles in a pH 7, 0.3 M NaCl, 0.025% SDS, 10 mM phosphate buffer solution for about 6 hours, and then the silicon substrate was washed with a 0.3-M ammonium acetate solution. In this way, Au-DNA conjugates were selectively immobilized to the surface of the silicon substrate (refer to reference numeral 160 of FIG. 3).

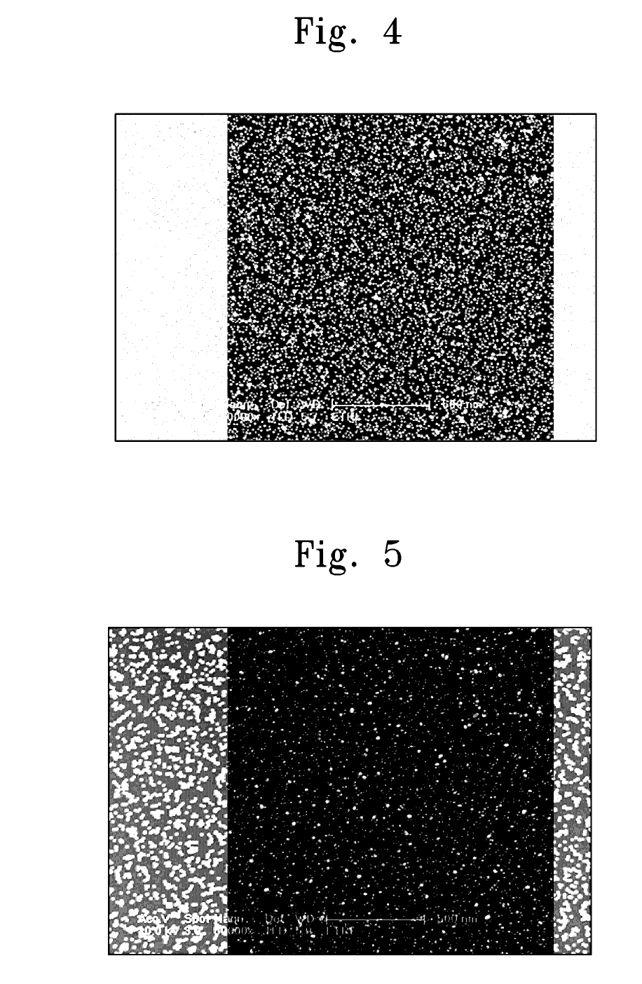

FIG. 4 is a scanning electron microscope (SEM) image taken from the surface of the silicon substrate to which Au-DNA conjugates are immobilized. Referring to FIG. 4, about 1800 Au-DNA conjugates are immobilized to 1 μm² of the surface of the silicon substrate.

### Comparative Example

In operation 3 of the above-described experimental example, APTES (a kind of an organic silane compound) was vaporized in atmospheric pressure to functionalize the surface of the silicon substrate (refer to reference numeral 110 of FIG. 3) modified with hydroxyl groups in operation 2; however, in this comparative example, a silicon substrate 110 modified with hydroxyl groups in operation 2 was placed for about 30 minutes in a solution prepared by dissolving 1% of APTES in ethanol under air atmosphere. Thereafter, the silicon substrate was rinsed with ethanol and was heated at about 120° C. for about 10 minutes to form amine groups on the surface of the silicon substrate. Other operations were performed on the silicon substrate in the same manner as the above-described experimental example. FIG. 5 is a SEM image taken from the surface of the silicon substrate to which Au-DNA conjugates are immobilized according to the comparative example. Referring to FIG. 5, about 1200 Au-DNA conjugates are immobilized to 1 μm² of the surface of the silicon substrate.

According to the present invention, in the method of immobilizing an active material on a surface of a substrate, the surface of the substrate is modified using a vaporized organic silane compound, so that a uniform, high-density, single molecular film can be reproducibly formed on the surface of the substrate by using the organic silane compound, and an active material can be immobilized to the surface of the substrate where the single molecular film is formed so as to allow immobilization of another active material to the surface of the substrate.

Furthermore, according to the method of the present invention, an organic silane compound is vaporized in a simple vessel at atmospheric pressure under inter gas atmosphere, and thus an evacuating process and the use of carrier gas are not necessary, so that inexpensive and simple processing is possible. In addition, according to the present invention, DNA bio molecules can be densely immobilized to a silicon substrate through strong chemical bonding, and thus other bio or functional molecules having amine groups can also be densely immobilized to the surface of the substrate. Therefore, the present invention is advantageous in mass production.

Moreover, the present invention provides technology for chemically activating a solid surface reproducibly and densely and functionalizing surfaces of wafers on a wafer basis by performing a silanizing reaction sensitive to reaction conditions using a vaporized silane compound, and the present invention also provides a method of densely immobilizing a functional bio material to the chemically activated solid surface through chemical bonding. Particularly, the present invention is useful for the cases where the thickness of a modified film should be precisely adjusted and a short single molecular film should be formed on a surface for fabricating a surface-sensitive sensor.

The above-disclosed subject matter is to be considered illustrative, and not restrictive, and the appended claims are intended to cover all such functionalizations, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of immobilizing an active material on a surface of a substrate, the method comprising:
cleaning a substrate;
functionalizing a surface of the substrate using a hydroxyl group;
functionalizing the surface of the substrate at atmospheric pressure using a vaporized organic silane compound; and
immobilizing an active material to an end of the surface of the substrate.

2. The method of claim 1, wherein the cleaning of the substrate comprises:
placing the substrate in boiling acetone;
placing the substrate in boiling methanol;
placing the substrate in a mixture solution of a sulfuric acid and a hydrogen peroxide; and
placing the substrate in a mixture of an ammonium fluoride and a hydrofluoric acid.

3. The method of claim 1, wherein the functionalizing of the surface of the substrate using the hydroxyl group comprises treating the surface of the substrate using oxygen plasma.

4. The method of claim 1, wherein the functionalizing of the surface of the substrate at atmospheric pressure using the vaporized organic silane compound comprises:
placing the substrate in a reaction vessel;
filling a solution vessel with an organic silane compound in an inert gas atmosphere, the solution vessel being disposed inside the reaction vessel at a position spaced apart from the substrate; and
vaporizing the organic silane compound filled in the solution vessel.

5. The method of claim 1, wherein the organic silane compound has the chemical formula: R₁—(CH₂)—Si(R₂R₃R₄)
where R₁ is at least one selected from the group consisting of ended or branched, acyclic or cyclic unsaturated hydrocarbon, thiol, carbonyl, carboxyl, amine, imine, nitro, hydroxyl, phenyl, nitrile, aldehyde, isocyano, and isothiocyano groups,
n is an integer ranging from 1 to 8, and
each of R₂, R₃, and R₄ is at least one selected from the group consisting of an alkyl group, an alkoxy group, and chlorine.

6. The method of claim 5, wherein the active material is a bio material, and the R₁ is at least one selected from the group consisting of aldehyde, isocyano, and isothiocyano groups.

7. The method of claim 1, wherein prior to the immobilizing of the active material, the method further comprises functionalizing the surface of the substrate using a functional group capable of reacting with the active material.

8. The method of claim 7, wherein the functional group is at least one selected from the group consisting of an amine group, a hydrazine group, a hydrazone group, a cyano group, an aldehyde group, an isocyano group, an isothiocyano group, a halogen group, a nitro group, a thiol group, and a Grignard compound.

9. The method of claim 7, wherein the active material is a bio material, and
the functional group is at least one selected from the group consisting of an aldehyde group, an isocyano group, and an isothiocyano group.

10. The method of claim 7, wherein the active material is a functional material, and
the functional group is at least one selected from the group consisting of acyclic or cyclic unsaturated hydrocarbon, thiol, carbonyl, carboxyl, amine, imine, nitro, hydroxyl, phenyl, nitrile, isocyano, and isothiocyano groups.

11. The method of claim 1, wherein the active material is at least one selected from the group consisting of a bio material, a functional material, a nano material, and a polymer.

12. The method of claim 1, wherein the substrate comprises at least one selected from the group consisting of crystalline silicon, crystalline germanium, amorphous silicon, amorphous germanium, SiₓN_{y}, SiO₂, Al₂O₃, TiO₂, Fe₂O₃, SnO, SnO₂, Ag₂O, CuO, Ce₂O₃, CeO₂, CoO, CO₃O₄, glass, compound semiconductor, and oxidized plastic.

13. The method of claim 1, wherein the substrate comprises at least one material selected from the group consisting of Teflon, aluminum, stainless steel, and glass.

14. The method of claim 11, wherein the bio material comprises at least one selected from the group consisting of DNA, RNA, antibody, antigen, oligopeptide, polypeptide, protein, enzyme, glucose, carbohydrate, anti-cancer material, amino acid, cell, bacterium, and virus.

15. The method of claim 11, wherein the functional material comprises at least one selected from the group consisting of a sterilizing active material, a gas adsorbing material, a chemical, molecules or a polymer having memory characteristics, molecules or a polymer having switching characteristics, a magnetic material, and a photonics material.

16. The method of claim 11, wherein the nano material has a size in the range from about 0.1 nm to about 999 nm and comprises at least one selected from the group consisting of quantum dots, nano dots, nano wires, nano tubes, nano porous materials, nano plates, nano rods, nano needles, nano powders, and nano cubes.

17. The method of claim 11, wherein the polymer has a molecular weight of 10,000 or higher and comprises a carbon compound including nitrogen, oxygen, or sulfur.
